(19) United States
(12) Patent Application Publication
(10) Pub. No.: US 2025/0112588 A1
(43) Pub. Date: Apr. 3, 2025

(54) FOLDABLE PHOTOVOLTAIC SOLAR PANEL ASSEMBLY FOR GENERATING AND SUPPLYING ELECTRIC ENERGY TO AN ORBITING SATELLITE

(71) Applicant: ASTRADYNE S.R.L., Bari (IT)

(72) Inventor: Alessia GLODER, Bitritto (Bari) (IT)

(21) Appl. No.: 18/537,988

(22) Filed: Dec. 13, 2023

(30) Foreign Application Priority Data
Sep. 29, 2023 (IT) 202023000003999

(51) Int. Cl. H02S 30/20; B64G 1/44; H02S 30/10; H05K 1/03

(52) U.S. Cl. CPC H02S 30/20; B64G 1/443; H02S 30/10; H05K 1/0393; H05K 2201/10143

(57) ABSTRACT

Provided is a foldable photovoltaic solar panel assembly for supplying electric energy to a satellite having a base made of a foldable textile material, with a bidimensional extension, that is reconfigurable between a deployed configuration, in which the base is completely deployed and essentially flat, and a folded configuration in which the base takes a three-dimensional shape of a cube that lacks a face. A plurality of rigid-flexible, printed circuit boards is fixed on the base. Each printed circuit board has a rigid part and a flexible layer for electrically connecting at least one pair of printed circuit boards to each other. A plurality of rigid photovoltaic cells, each fixed on the rigid part of a respective printed circuit board generates an electric current when hit by light radiation.

### CROSS-REFERENCE TO RELATED APPLICATION

This application claims priority to Italian Patent Application No. 202023000003999 filed on Sep. 29, 2023, the contents of which is incorporated by reference in its entirety.

### TECHNICAL FIELD

The present invention relates to a foldable photovoltaic solar panel assembly configured to generate and supply electric energy to a satellite when the latter is orbiting.

### PRIOR ART

Satellites are often powered by means of photovoltaic solar panels. As a general rule, the electric power supplied by photovoltaic solar panels is directly proportional to their operational surface area. For this reason, apart from in the case of very small satellites or satellites with an extremely short operational mission and therefore an extremely low power requirement, the photovoltaic solar panels necessarily have generally rather large areas and are therefore arranged upon photovoltaic solar panel structures that are foldable. This is necessary in so far as the dimensional and volumetric requirements of the launchers and of the satellite platforms are extremely stringent. The photovoltaic solar panel assembly is consequently installed on the satellite and arranged inside the launcher in the folded mode, and is then deployed once the satellite has been launched and has reached the target orbit. For the manufacture of deployable photovoltaic solar panel structures, various technologies have been developed, which may be grouped into two groups: flexible and rigid structures. Flexible structures are a more recent light and compact technology that makes use of flexible photovoltaic cells that are themselves folded. Unfortunately, in the current state of the art, such flexible photovoltaic cells are clearly less efficient when compared to rigid photovoltaic cells and are more easily damaged. Conversely, deployable rigid structures are an extremely consolidated and much used technology, wherein a rigid foldable assembly having hinges and being actuated by means of preloaded springs or dedicated electric motors unfolds and positions a plurality of rigid photovoltaic cells. Rigid photovoltaic cells have a high efficiency, even up to 28-32%, but require dedicated deployment means and an adequate structural support layer which results in a not inconsiderable weight gain. Furthermore, the photovoltaic cells are rigid and the layer that supports them is not flexible but only foldable along specific folding lines; this implies that—even in the folded configuration—these types of systems occupy a rather large surface area. Malfunctions associated with the deployment system, in the cables or in the hinges are amongst the most common mission failures for satellites that employ such photovoltaic solar panel structures.

### SUMMARY OF THE INVENTION

The object of this invention is, therefore, to provide a foldable photovoltaic solar panel assembly which overcomes the disadvantages of the prior art.

In particular, an object of the present invention is to provide a foldable photovoltaic solar panel assembly that may employ high performance photovoltaic cells, such as rigid photovoltaic cells, but that does not, at the same time, suffer the malfunctioning risks associated with the deployment system and associated hinges and structures, whilst respecting the stringent constraints imposed by the launcher and the satellite platforms.

This and other objects are fully achieved according to the present invention by a foldable photovoltaic solar panel assembly as described and claimed herein.

Advantageous embodiments of the present invention are also described.

In summary, the present invention provides a foldable photovoltaic solar panel assembly configured to generate and supply electric energy to a satellite, for example when the satellite is in orbit, the photovoltaic solar panel assembly comprising:
a base, made of a foldable textile material, the base having an essentially bidimensional extension or like a thin plate, and comprising a first side and a second side, arranged opposite the first side; the base being reconfigurable between a deployed configuration in which the base is completely deployed and essentially flat, and a folded configuration in which the base takes a three-dimensional shape of a cube that lacks a face or a three-dimensional shape that, when placed on a face of a cube, is adapted to cover five of the six faces of the cube;
a plurality of rigid-flexible, printed circuit boards, arranged fixed on the first side of the base, each comprising in turn at least one rigid part and a flexible layer, the rigid part in turn comprising at least one support layer and a copper layer supported by the support layer, each flexible layer being adapted to electrically connect at least one pair of printed circuit boards to each other; and
a plurality of rigid photovoltaic solar cells, each photovoltaic solar cell of the plurality of rigid photovoltaic solar cells being arranged fixed on the rigid part of a respective printed circuit board and being adapted to generate an electric current when hit by light radiation and to transmit said electric current to said respective copper layer.

According to one preferred embodiment of the present invention, all of the photovoltaic cells have the same size and an essentially squared shape in such a way that the assembly may be compatible with a cubesat, i.e. with a cube shaped satellite, or at least with a part of its frame having a cubic shape. In such case, even more preferably, each photovoltaic cell has a side length comprised between about 7 cm and about 9 cm, and in the most preferable embodiment of the invention it has a side length of about 8 cm.

According to an embodiment, the photovoltaic solar panel assembly further comprises deployment means arranged so as to exert a force on the second side of the base, and adapted to cause, by exerting said force, the reconfiguration of the base from the folded configuration to the deployed configuration. In such case, preferably, the deployment means are further adapted to cause the reconfiguration of the base from the deployed configuration to the folded configuration.

According to an embodiment, the base, in the deployed configuration, has a shape in plan given by the union of a central square, a photovoltaic solar cell of the plurality of photovoltaic cells preferably being arranged at the centre of said central square, and of four equal, lateral squares, arranged around the central square and contiguous with the latter, each of the four lateral squares having an area equal to at least nine times the area of the central square, seven photovoltaic solar cells of the plurality of photovoltaic solar cells being arranged on each of the four lateral squares, six of which are aligned in two rows of three, and one is aligned diagonally relative to the central square.

According to an embodiment, each photovoltaic cell is directly welded on the rigid part of a respective printed circuit board. In such case, in one embodiment of the invention, the base has, on its first side, a depression or a recess or a region in which the material of the base has been partially removed, at the point of welding between each photovoltaic solar cell and the rigid part of the respective printed circuit board, in order to allow, within such region, welding between the photovoltaic cell and the layer of copper of the rigid part of the respective printed circuit board.

According to an embodiment, the ratio of the surface of the first side of the base in the deployed configuration to the sum of the non-covered surfaces of the first side of the base in the folded configuration is at least 7 to 1.

According to an embodiment, the base is made at least partially of meta-aramid fibre. In a further embodiment, the base is made partially of meta-aramid fibre and partially of para-aramid fibre.

According to an embodiment, the flexible layer of each printed circuit board is made of polyamide.

According to an embodiment, the rigid part of the printed circuit boards further comprises at least one pre-impregnated fibre reinforced composite material layer, interposed between the support layer and the first side of the base.

According to an embodiment, the copper layer of each printed circuit board is interposed between the support layer of each printed circuit board and the first side of the base and/or between the support layer of each printed circuit board and the flexible layer of each printed circuit board. Clearly, it is also possible that each printed circuit board comprises more than one copper layer.

Advantageously, the distance between one photovoltaic cell and an adjacent photovoltaic cell increases radially towards the outside of the base in order to accommodate a greater number of folding lines in moving away from the centre of the base.

Another object of the present invention is to provide a satellite comprising:
a frame shaped as a cube; and
a photovoltaic solar panel assembly according to any embodiment according to the first aspect of the present invention;
wherein the photovoltaic solar panel assembly is arranged fixed on the frame in such a way that, in the folded configuration, the base covers all the faces of the frame but one.

In such case, preferably, the base, in the deployed configuration, has a shape in plan given by the union of a central square, a photovoltaic solar cell of the plurality of photovoltaic cells preferably being arranged at the centre of said central square, and of four equal, lateral squares, arranged around the central square and contiguous with the latter, each of the four lateral squares having an area equal to at least nine times the area of the central square, seven photovoltaic solar cells of the plurality of photovoltaic solar cells being arranged on each of the four lateral squares, six of which are aligned in two rows of three, and one is aligned diagonally relative to the central square, and the photovoltaic solar panel assembly is arranged fixed on the frame in such a way that, in both the folded configuration and the deployed configuration the central square is arranged on one face of the frame and has the same dimensions thereof.

### BRIEF DESCRIPTION OF THE DRAWINGS

The features and advantages of the present invention will be clarified by the detailed description that follows, given purely by way of non-limiting example and with reference to the attached drawings, in which:

FIG. 1 is a view of a satellite having a photovoltaic solar panel assembly according to one embodiment of the invention shown successively in three different phases, in particular, from left to right, a phase wherein the photovoltaic solar panel assembly is closed, a phase wherein the photovoltaic solar panel assembly is being deployed, and a phase wherein the photovoltaic solar panel assembly has been completely deployed;

FIG. 2 is a plan view of a photovoltaic solar panel assembly according to the embodiment of the invention shown in FIG. 1 in a completely deployed configuration;

FIG. 3 is a detail view of that shown in FIG. 2;

FIG. 4 is a sectional side view of a photovoltaic solar panel assembly, according to an embodiment of the invention;

FIG. 5 is a sectional side view of a photovoltaic solar panel assembly according to a further embodiment of the invention; and

FIG. 6 is a view of the satellite of FIG. 1, in the phase wherein the photovoltaic solar panel assembly is completely deployed, from a different angular view.

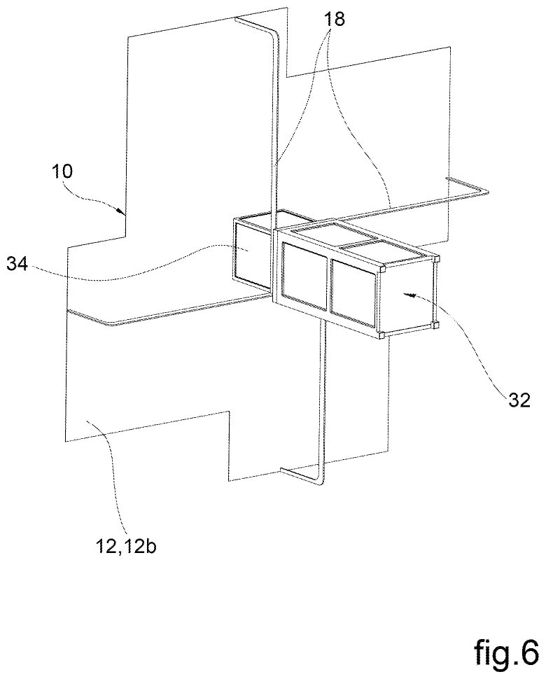

### DETAILED DESCRIPTION

With reference to the figures, the photovoltaic solar panel assembly according to the present invention is indicated generally with the reference numeral 10.

The photovoltaic solar panel assembly 10 is foldable and deployable after the launch, and is configured to generate and electric energy and to supply it, directly or indirectly, to a satellite or to its subsystems, and to this end essentially comprises a base 12, a plurality of printed circuit boards 14 and a plurality of photovoltaic cells 16.

The base 12 is made in textile or fabric material and is foldable, preferably in such a way that it may be superimposed upon itself, or in such a way that it may be folded upwards or downwards by 180°. For example, the base 12 may be made partially or completely in a meta-aramid fibre. Advantageously, the base 12 is made partially in meta-aramid fibre and partially in para-aramid fibre. In the preferable embodiment of the invention, the base 12 is made as 80% in a meta-aramid fibre and 20% in a para-aramid fibre; however, configurations wherein, other than the para-aramid fibre and the meta-aramid fibre, the base 12 comprises other components or materials, are not excluded. The base 12 does not therefore require a rigid layer but itself provides a flexible layer for supporting the printed circuit boards 14 and the photovoltaic cells 16. In any case, the material used for the base 12 is such to ensure sufficient thermal resistance and sufficient mechanical resistance to folding, flexing and stretching cycles that are also repeated over short time intervals.

The base 12 has an essentially bidimensional extension, or in the form of a thin plate, and comprises a first side 12a and a second side 12b, arranged opposite the first side 12a, but may be made with using different planar shapes in plan. For example, the base 12 may have a square shape in plan, or essentially the shape in plan of a rectangular quadrangle, or else, for example, the base 12 may have the shape in plan of a grid or of a series of strips of material arranged orthogonally to each other and defining therefore, in their entirety, essentially a quadrangular shape or another flat shape but nonetheless having a plurality of empty quadrangular spaces arranged as a grid.

The thickness of the base 12 is extremely reduced, preferably of the order of 1 mm or less, and still more preferably a thickness of less than 0.5 mm, for example a thickness of 0.45 mm; according to one particularly preferable embodiment of the invention, this thickness is constant.

According to the present invention, the base 12, being foldable, may be reconfigured at least from a folded configuration to a deployed configuration, and preferably may also be reconfigured from a deployed to a folded configuration. Even more advantageously, the base 12 may be reconfigured from the deployed to the folded configuration and vice versa. To this end, the photovoltaic solar panel assembly 10 may comprise deployment means 18, which are arranged in such a way to exert, when thus actuated, a force on base 12, preferably on the second side 12b of the base 12, and to cause, by exerting said force, the reconfiguration of the base 12 from the folded configuration to the deployed configuration and, as mentioned, preferably also from the deployed configuration to the folded configuration. The deployment means 18 may be made in different embodiments, for example by means of preloaded springs, driven tie-rods, linear actuators, for example electric linear actuators and so on.

In the folded configuration, the base 12 takes a three-dimensional shape of a cube that lacks a face, or takes a three-dimensional shape corresponding to five contiguous faces of a cube, with the sixth face left free, or empty. In the deployed configuration, instead, the base 12 takes an essentially flat shape. In the most preferable embodiment of the invention, the ratio of the surface of the first side 12a of the base 12 in the deployed configuration to the sum of all of the non-covered surfaces, or whereupon there is not overlaid a further part of the base 12, of the first side 12a of the base 12 in the folded configuration is at least 7 to 1, and is for example 7.4 to 1, or 37 to 5.

On the base 12, and in particular on the first side 12a of the base 12, printed circuit boards 14 are arranged, and on every printed circuit board 14 a respective photovoltaic cell 16 is arranged fixed. The printed circuit boards 14 are supplied as printed circuit boards of the rigid-flexible type, i.e. they comprise rigid and flexible parts. Preferably, the total thickness of each printed circuit board 14 is of between 0.5 mm and 2 mm.

In particular, every printed circuit board 14 comprises at least on rigid part 21 and one flexible layer 22.

The rigid part 21 provides the necessary robustness and rigidity for supporting the respective photovoltaic cells 16, as well as ensuring the electronic functionality. In particular, the rigid part 21 comprises a support layer 20 and a copper layer 26 supported by such support layer 20. The support layer 20 has, preferably, a maximum thickness of 0.5 mm. Advantageously, the rigid part 21 further comprises at least one pre-impregnated fibre reinforced composite material layer 24, interposed between the support layer 20 of each printed circuit board 14 and the first side 12a of the base 12. Advantageously, another pre-impregnated fibre reinforced composite material layer 24 is also arranged between the support layer 20 of each printed circuit board 14 and the respective flexible layer 22.

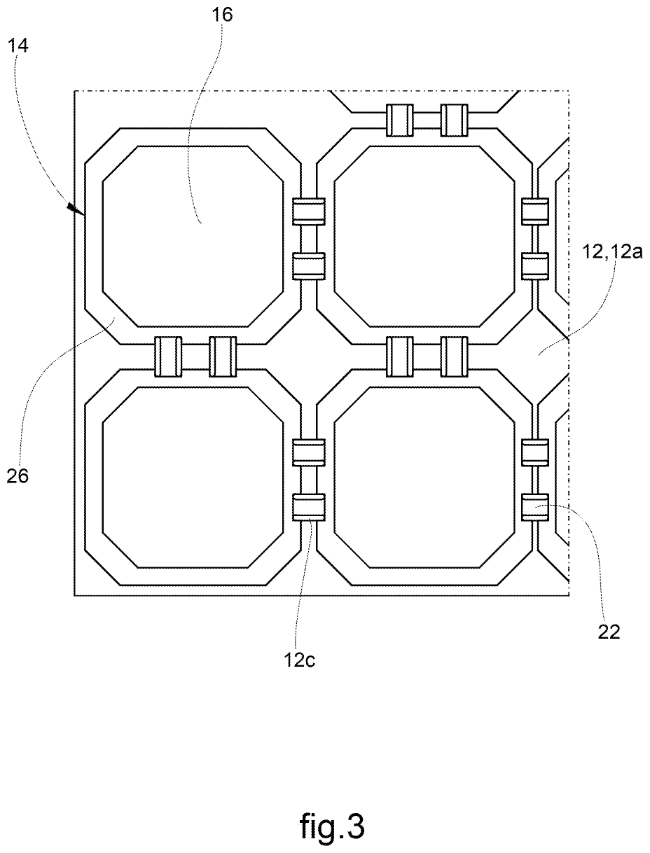

The flexible layers 22 are adapted to electrically connect to each other at least one pair of adjacent printed circuit boards 14, and preferably—as shown in FIG. 3—all of the printed circuit boards 14 to each other, for example two by two. By virtue of the flexible layers 22, it is possible to obtain an electric interconnection between the printed circuit boards 14 without the necessity of external cabling.

Advantageously, the printed circuit boards 14, or at least flexible components, or the flexible layers 22, are made as one piece or integrally as one piece. Advantageously, according to the most preferable embodiment of the invention, the flexible layers 22 are made of polyamide or comprise at least one part in polyamide. According to the invention, the rigid part 21 of each printed circuit board 14—as mentioned—further comprises a copper layer 26, that is preferably interposed between the support layer 20 of each printed circuit board 14 and the first side 12a of the base and/or between the support layer 20 of each printed circuit board 14 and the flexible layer 22 of the same printed circuit board 14.

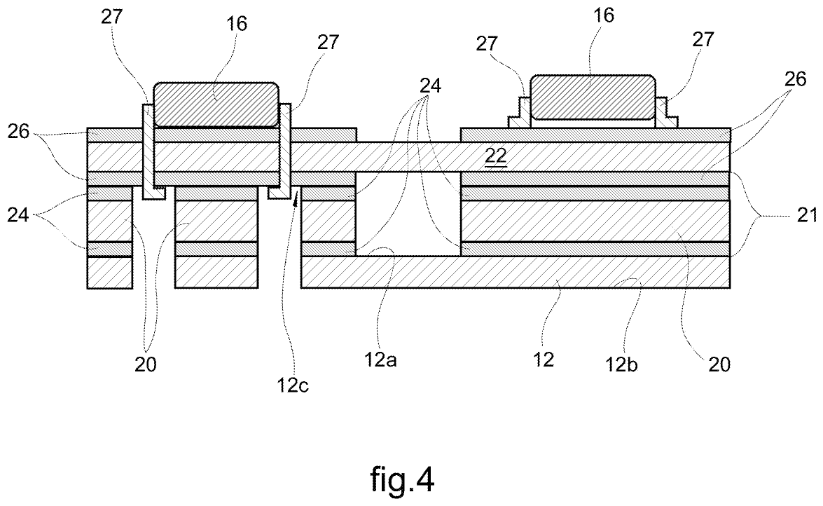

In particular, according to a first particularly advantageous embodiment of the present invention, shown in FIG. 4, a stack of overlapping layers is defined as follows. Starting from the base 12, and in particular from the first side 12a of the base 12, there are arranged in succession, one on top of the other, firstly a printed circuit board 14 rigid part 21, then a flexible layer 22 and then a further copper layer 26 whereupon, finally, a photovoltaic cell 16 is fixed. The rigid part 21, in this case, comprises, in order from bottom to top of FIG. 4, a first pre-impregnated fibre reinforced composite material layer 24, a support layer 20, a second pre-impregnated fibre reinforced composite material layer 24, and then a copper layer 26.

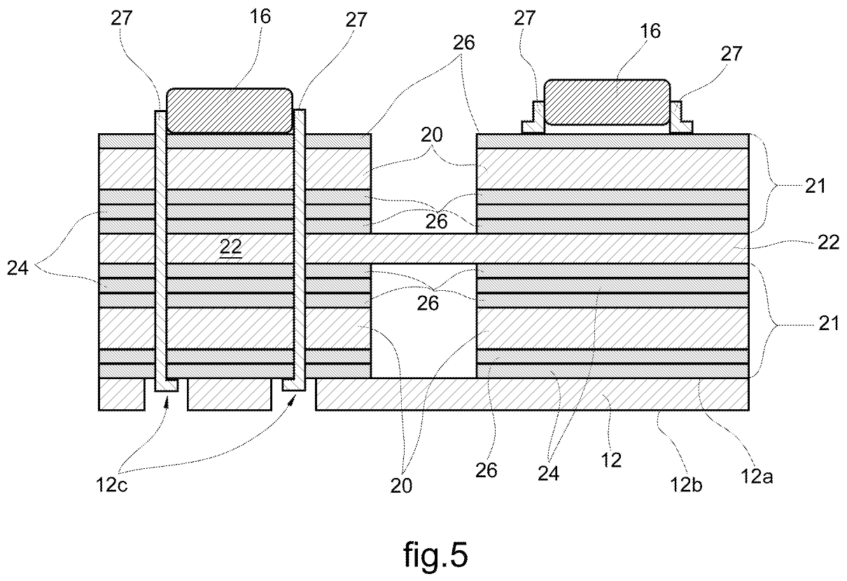

In particular, according to a further particularly advantageous embodiment of the present invention, shown in FIG. 5, a stack of overlapping layers is defined as follows. Starting from the base 12, and in particular from the first side 12a of the base 12, there are arranged in succession, one on top of the other, firstly a first printed circuit board 14 rigid part 21, then a flexible layer 22 and then a second rigid part 21, whereupon, finally, a photovoltaic cell 16 is fixed. The first rigid part 21 comprises, in this case, in order from bottom to top of FIG. 5, a first pre-impregnated fibre reinforced composite material layer 24, a copper layer 26, a support layer 20, a further copper layer 26, then a further pre-impregnated fibre reinforced composite material layer 24, and then finally a further copper layer 26. The second rigid part 21 comprises, in this case, in order from bottom to top of FIG. 5, a copper layer 26, a pre-impregnated fibre reinforced composite material layer 24, a further copper layer 26, then a support layer 20, and then a further copper layer 26.

The photovoltaic cells 16, in fact, are directly fixed to the rigid part 21 of each printed circuit board 14. The electric connection to the copper layers 26 may be made by means of specific electric connection strips 27, directly on the most outer copper layer 26, or the furthest away from the first side 12a of the base 12, or else on the most inner copper layer 26, or the nearest to, or in direct contact with, the first side 12a of the base 12. In the latter case, in order to facilitate the procedure of welding the electric connection strips 27 from the photovoltaic cell 16 to the copper layer 26, the base 12 has, on the first side 12a, at the point of welding between each photovoltaic solar cell 16 and the rigid part 21 of the respective printed circuit board 14, a recess 12c, or a region wherein the base 12 is partially or totally removed.

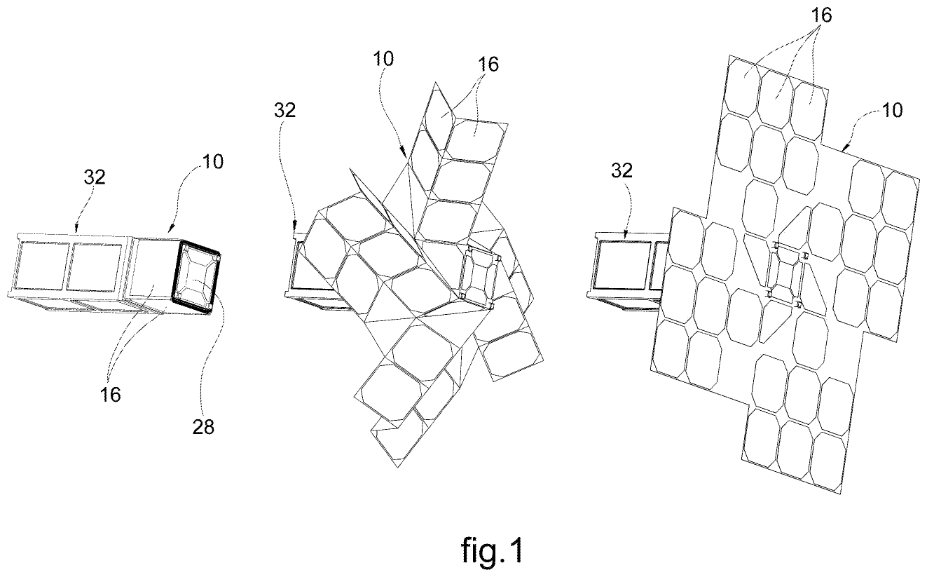

All the photovoltaic cells 16 preferably have the same size and still more preferably have an essentially square shape, in such a way as to facilitate the design of the entire photovoltaic solar panel assembly 10 and to make it easier to design the deployment and eventual re-folding procedure. As may be seen in FIGS. 1, 2 and 3 in the context of the present invention, with reference to the photovoltaic cells 16, octagonal shapes obtained by chamfering a square also fall within the meaning of ‘square’ shape, i.e. regular octagons wherein four long sides are alternated with four much shorter sides. Preferably, each photovoltaic cell 16 is of a square shape and has a side with a length of between about 7 cm and about 9 cm, more preferably of about 8 cm. It is also possible to use photovoltaic cells 16 of a different shape, but that preferably cover square areas, such as for example pairs of triangular photovoltaic cells. In a manner known per se, the photovoltaic cells 16 are adapted to generate an electric current when hit by light radiation and to transmit such current to an underlying copper layer 26 and part of the respective printed circuit board 14. The photovoltaic cells 16 are of themselves, per se, in rigid and non-foldable or flexible elements.

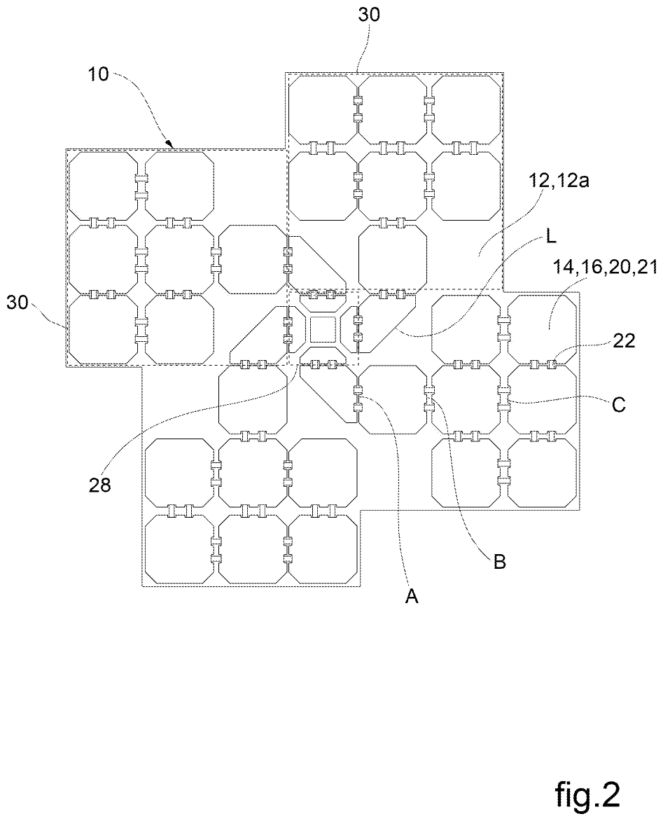

In the most preferable embodiment of the invention, shown in FIG. 2, the base 12 has a particular shape in plan which is clearly visible in the deployed configuration, and essentially given by the combination of other shapes. In particular, the base 12 comprises a central square 28 and four lateral squares 30 that are equal to each other and arranged around the central square 28. Although not illustrated in the embodiments, a photovoltaic cell 16 may be arranged within the central square. The four lateral squares 30 each have an area equivalent to at least nine times that of the central square 28. Every lateral square 30 is arranged in contact with, or continuously with, the central square 28, in such a way that one side of every lateral square 30 is overlapped by a respective different side of the central square 28, and in such a way that a vertex of such a lateral square 30 coincides with the vertex of such a respective different side of the central square 28. The lateral squares 30 are arranged in such a way as not to be superimposed one above the other. On each of the lateral square 30 there are arranged at least seven photovoltaic cells 16, whereof at least six are arranged aligned to each other in a configuration of two rows by three columns or three rows by two columns. A seventh photovoltaic cell 16 is arranged on every lateral square 30, diagonally in relation to the central square 28. In such an embodiment, four different folding lines extend radially starting from the four vertices of the central square 28. Such four folding lines L are rectilinear and inclined by 90% each with respect to the previous and the next, moving clockwise.

In the most preferable embodiment of the invention, as clearly visible from the example in FIG. 2, the distance between one photovoltaic cell 16 and an adjacent photovoltaic cell 16 increases in moving away from the centre of the base 12 towards the outside of the same base 12. In fact, the distance between the two successive photovoltaic cells 16 at point A is less than the distance between the two successive photovoltaic cells 16 at point B, which in turn is less than the distance between the two successive photovoltaic cells 16 at point C (see FIG. 2).

Whilst in FIG. 2 the shape in plan of the base 12 is continuous, or it is filled, there is nothing to exclude it being made in maintaining the same general shape and a similar outer perimeter, but using an unfilled shape, for example a shape obtained from the overlapping of strips.

Also forming part of the invention is a satellite 32, comprising a frame 34 and a photovoltaic solar panel assembly 10. The frame 34 is a structural essentially cube shaped frame, preferably of dimensions that are less than 10 cm×10 cm. The satellite 32 may also comprise other frames 34, preferably also these being cube shapes and connected or integral to the frame 34. The photovoltaic solar panel assembly 10 is arranged fixed on the frame 34 in such a way that, in the folded configuration, the base 12 covers all the faces of the frame 34 but one. In particular, preferably, the photovoltaic solar panel assembly 10 is arranged on the frame 34 in such a way that the in the folded and deployed configuration the central square 28 of the base 12 is arranged in such a way as to cover only one face of the frame 34, and wherein the central square 28 has sides with essentially the same length as the side of such a square face of the frame 34. The satellite 32 may further comprise an electric energy storage system, for example a battery adapted to store, in the form of chemical energy, the electric energy generated by the photovoltaic cells 16. To this end, furthermore, the satellite 32 comprises a power distribution system comprising electric power and/or digital signal transmission cables that are known per se.

The photovoltaic solar panel assembly 10 is configured to be arranged on a satellite 32 and, once deployed, to generate electric energy and to supply it to such satellite 32. In an equivalent manner, however, it is possible to configure the same photovoltaic solar panel assembly 10 for other applications, such as for example arranging a photovoltaic solar panel assembly on other types of vehicle or aircraft or on fixed ground structures to be able to fold the base 12 when the meteorological conditions are suitable o dangerous or risk damage to the photovoltaic solar panel assembly 10 and then to be able to deploy it only when the meteorological conditions become acceptable again.

As may be seen from the preceding description, by virtue of the photovoltaic solar panel assembly according to the invention, the objects of the above-described invention may be fully achieved, resulting in several advantages.

In particular, the invention provides a foldable photovoltaic solar panel assembly that has been improved in comparison to the prior art.

Above all, by virtue of the combination of a flexible base and rigid and flexible layers in the printed circuit boards, it is possible to obtain a foldable photovoltaic solar panel assembly that combines the advantages of rigid photovoltaic cells with the advantages of flexible electronic components. In particular, by virtue of the presence of the flexible layers that are used to electrically connect the printed circuit boards to each other, and arranged on the base which is also foldable, it is possible to fold, refold and deploy the photovoltaic solar panel assembly even if this does not comprise foldable or flexible photovoltaic cells but only rigid photovoltaic cells. Furthermore, by virtue of the fact that the base is made of a textile or fabric material, it may be folded up until being totally overlapping, implementing folds upwards or downwards by 180°, and, in absorbing mechanical stresses, it protects flexible layers which are also foldable, from damage that would otherwise provoke mechanical stresses of both fatigue and tension or stretching. The use of textile or fabric materials, furthermore allows the base to be folded with extremely reduced radii of curvature.

Without prejudice to the principle of the invention, the embodiments and construction details may vary widely with respect to that which has been described and illustrated purely by way of non-limiting example, without thereby departing from the scope of protection as described and claimed herein.

What is claimed is:

1. A foldable photovoltaic solar panel assembly configured to generate and supply electrical energy to a satellite when the satellite is orbiting, the foldable photovoltaic solar panel assembly comprising:
a base made of a foldable textile material, the base having an essentially bidimensional extension or like a thin plate, and comprising a first side and a second side, arranged opposite the first side; the base being reconfigurable between a deployed configuration in which the base is completely deployed and essentially flat, and a folded configuration in which the base takes a three-dimensional shape of a cube that lacks a face or a three-dimensional shape that, when placed on a face of a cube, is adapted to cover five of the six faces of said cube;
a plurality of rigid-flexible, printed circuit boards, arranged fixed on the first side of the base, each comprising at least one rigid part and a flexible layer, the rigid part in turn comprising at least one support layer and a copper layer supported by the support layer, each flexible layer being adapted to electrically connect at least one pair of printed circuit boards to each other; and
a plurality of rigid photovoltaic solar cells, each photovoltaic solar cell of the plurality of rigid photovoltaic solar cells being arranged fixed on the rigid part of a respective printed circuit board and being adapted to generate an electric current when hit by light radiation and to transmit said electric current to said respective copper layer.

2. The foldable photovoltaic solar panel assembly of claim 1, wherein the rigid photovoltaic solar cells have all a same size and an essentially squared shape.

3. The foldable photovoltaic solar panel assembly of claim 2, wherein each photovoltaic solar cell has a side length comprised between about 7 cm and about 9 cm.

4. The foldable photovoltaic solar panel assembly of claim 1, further comprising deployment means arranged so as to exert a force on the second side of the base, and adapted to cause, by exerting said force, a reconfiguration of the base from the folded configuration to the deployed configuration.

5. The foldable photovoltaic solar panel assembly of claim 4, wherein the deployment means are further adapted to cause the reconfiguration of the base from the deployed configuration to the folded configuration.

6. The foldable photovoltaic solar panel assembly of claim 1, wherein the base, in the deployed configuration, has a shape in plan given by the union of a central square and of four equal, lateral squares, arranged around the central square and contiguous with the central square, each of the four lateral squares having an area equal to at least nine times an area of the central square, seven photovoltaic solar cells of the plurality of rigid photovoltaic solar cells being arranged on each of the four lateral squares, six of which are aligned in two rows of three, and one is aligned diagonally relative to the central square.

7. The foldable photovoltaic solar panel assembly of claim 1, wherein each photovoltaic solar cell is welded on the rigid part of the respective printed, and wherein the base comprises, on the first side, a recess or a region in which the foldable textile material of the base has been partially removed, at a point of welding between each photovoltaic solar cell and the rigid part of the respective printed circuit board.

8. The foldable photovoltaic solar panel assembly of claim 1, wherein a ratio of a surface of the first side of the base in the deployed configuration to a sum of non-covered surfaces of the first side of the base in the folded configuration is at least 7 to 1.

9. The foldable photovoltaic solar panel assembly of claim 1, wherein the base is made at least partially of meta-aramid fibre.

10. The foldable photovoltaic solar panel assembly of claim 1, wherein the flexible layer of each printed circuit board is made at least partially of polyamide.

11. The foldable photovoltaic solar panel assembly of claim 1, wherein the rigid part of the printed circuit boards further comprises at least one pre-impregnated fibre reinforced composite material layer interposed between the support layer and the first side of the base.

12. The foldable photovoltaic solar panel assembly of claim 1, wherein the copper layer of each printed circuit board is interposed between the support layer of each printed circuit board and the first side of the base and/or between the support layer of each printed circuit board and the flexible layer of each printed circuit board.

13. The foldable photovoltaic solar panel assembly of claim 1, wherein a distance between a photovoltaic solar cell and an adjacent or following photovoltaic solar cell increases from a centre of the base outwards the base.

14. A satellite comprising:
a frame shaped as a cube; and
a photovoltaic solar panel assembly configured to generate and supply electrical energy to a satellite when the satellite is orbiting, the foldable photovoltaic solar panel assembly comprising:
a base made of a foldable textile material, the base having an essentially bidimensional extension or like a thin plate, and comprising a first side and a second side, arranged opposite the first side; the base being reconfigurable between a deployed configuration in which the base is completely deployed and essentially flat, and a folded configuration in which the base takes a three-dimensional shape of a cube that lacks a face or a three-dimensional shape that, when placed on a face of a cube, is adapted to cover five of the six faces of said cube;
a plurality of rigid-flexible, printed circuit boards, arranged fixed on the first side of the base, each comprising at least one rigid part and a flexible layer, the rigid part in turn comprising at least one support layer and a copper layer supported by the support layer, each flexible layer being adapted to electrically connect at least one pair of printed circuit boards to each other; and
a plurality of rigid photovoltaic solar cells, each photovoltaic solar cell of the plurality of rigid photovoltaic solar cells being arranged fixed on the rigid part of a respective printed circuit board and being adapted to generate an electric current when hit by light radiation and to transmit said electric current to said respective copper layer;
wherein the photovoltaic solar panel assembly is arranged fixed on the frame in such a way that, in the folded configuration, the base covers all faces of the frame but one.

15. The satellite of claim 14, wherein the base, in the deployed configuration, has a shape in plan given by the union of a central square and of four equal, lateral squares, arranged around the central square and contiguous with the central square, each of the four lateral squares having an area equal to at least nine times an area of the central square, seven photovoltaic solar cells of the plurality of rigid photovoltaic solar cells being arranged on each of the four lateral squares, six of which are aligned in two rows of three, and one is aligned diagonally relative to the central square, and wherein the photovoltaic solar panel assembly is arranged fixed on the frame in such a way that, both in the folded configuration and in the deployed configuration, the central square is arranged on a face of the frame and has the same size thereof.

16. The foldable photovoltaic solar panel assembly of claim 2, wherein each rigid photovoltaic solar cell has a side length of about 8 cm.

17. The foldable photovoltaic solar panel assembly of claim 6, wherein a photovoltaic solar cell of the plurality of rigid photovoltaic cells is arranged at a centre of the central square.

18. The foldable photovoltaic solar panel assembly of claim 1, wherein the base is made partially of meta-aramid fibre and partially of para-aramid fibre.
